(19) United States
(12) Patent Application Publication
(10) Pub. No.: US 2024/0276852 A1
(43) Pub. Date: Aug. 15, 2024

(54) DISPLAY DEVICE

(71) Applicant: Sharp Display Technology Corporation, Kameyama City, Mie (JP)

(72) Inventor: Youhei NAKANISHI, Kameyama City, Mie (JP)

(21) Appl. No.: 18/566,771

(22) PCT Filed: Aug. 18, 2021
(86) PCT No.: PCT/JP2021/030226

§ 371 Date: Dec. 4, 2023

(51) Int. Cl. H10K 59/80; H10K 59/122; H10K 59/35

(52) U.S. Cl. CPC H10K 59/8791; H10K 59/122; H10K 59/80518; H10K 59/353

(57) ABSTRACT

A display device includes: a base substrate layer; a thin film transistor layer provided on the base substrate layer; and a light-emitting element layer provided on the thin film transistor layer, the light-emitting element layer including a plurality of pixel electrodes, a common edge cover, a plurality of light-emitting function layers, and a common electrode layered in order corresponding to a plurality of subpixels constituting a display region, wherein the edge cover covers a peripheral edge portion of each of the pixel electrodes, in each of the subpixels, a portion of the plurality of pixel electrodes exposed from the edge cover constitutes a light-emitting region, and a portion of the plurality of pixel electrodes overlapping the edge cover constitutes a non-light-emitting region, and a reflective surface having an uneven shape is provided in the non-light-emitting region.

### TECHNICAL FIELD

The disclosure relates to a display device.

### BACKGROUND ART

In recent years, a self-emission organic electroluminescence (hereinafter also referred to as EL) display device using organic EL elements has attracted attention as a display device that can replace liquid crystal display devices (e.g., see PTL 1).

### CITATION LIST

### Patent Literature

PTL 1: JP 6588299 B

### SUMMARY

### Technical Problem

However, a self-emission display device such as an organic EL display device is configured such that, in light-emitting elements in which pixel electrodes, light-emitting function layers, and common electrodes are layered in order, light emitted from the light-emitting function layers is reflected by the pixel electrodes and emitted to the front via the common electrodes, and thus external light is also reflected by the pixel electrodes. In this configuration, since display quality is significantly degraded in a bright environment, a circular polarizer is attached to a surface of the display device. Here, when a circular polarizer is used, half or more of the light emitted from the light-emitting function layers is lost at the circular polarizer, which causes poor luminous efficiency, and thus there is room for improvement.

The disclosure has been made in view of the above circumstance, and an objective of the disclosure is to prevent display quality from degrading due to reflection of external light without using a circular polarizer.

### Solution to Problem

In order to achieve the objective, a display device according to the disclosure includes a base substrate layer, a thin film transistor layer provided on the base substrate layer, and a light-emitting element layer provided on the thin film transistor layer, the light-emitting element layer including a plurality of pixel electrodes, a common edge cover, a plurality of light-emitting function layers, and a common electrode layered in order corresponding to a plurality of subpixels constituting a display region, in which the edge cover covers a peripheral edge portion of each of the pixel electrodes, in each of the subpixels, a portion of the plurality of pixel electrodes exposed from the edge cover constitutes a light-emitting region, and a portion of the plurality of pixel electrodes overlapping the edge cover constitutes a non-light-emitting region, and a reflective surface having an uneven shape is provided in the non-light-emitting region.

### Advantageous Effects of Disclosure

According to the disclosure, degraded display quality due to reflection of external light can be prevented without using a circular polarizer.

### BRIEF DESCRIPTION OF DRAWINGS

FIG. 1 is a plan view illustrating a schematic configuration of a display device according to a first embodiment of the disclosure.

FIG. 2 is a plan view illustrating a detailed configuration of a display region of the display device according to the first embodiment of the disclosure.

FIG. 3 is a cross-sectional view of the display region of the display device according to the first embodiment of the disclosure.

FIG. 4 is an equivalent circuit diagram of a TFT layer constituting the display device according to the first embodiment of the disclosure.

FIG. 5 is a cross-sectional view illustrating a light-emitting function layer constituting the display device according to the first embodiment of the disclosure.

FIG. 6 is a plan view illustrating a detailed configuration of a display region of a display device according to a second embodiment of the disclosure, and is a view corresponding to FIG. 2.

FIG. 7 is a cross-sectional view of a display region of a display device according to a third embodiment of the disclosure, and is a view corresponding to FIG. 3.

FIG. 8 is a cross-sectional view of a display region of a display device according to a fourth embodiment of the disclosure, and is a view corresponding to FIG. 3.

FIG. 9 is a plan view illustrating a detailed configuration of a display region of a display device according to a fifth embodiment of the disclosure, and is a view corresponding to FIG. 2.

FIG. 10 is a plan view illustrating a detailed configuration of a display region of a display device according to a sixth embodiment of the disclosure, and is a view corresponding to FIG. 2.

FIG. 11 is a cross-sectional view of a display region of a display device according to a seventh embodiment of the disclosure, and is a view corresponding to FIG. 3.

### DESCRIPTION OF EMBODIMENTS

Embodiments of the disclosure will be described below in detail with reference to the drawings. Further, the disclosure is not limited to the embodiments to be described below.

### First Embodiment

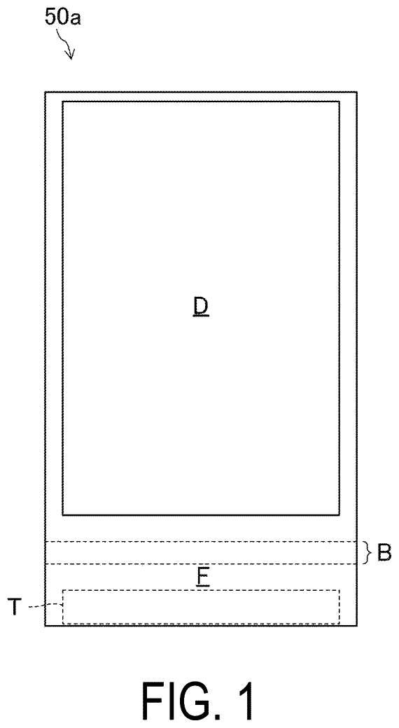

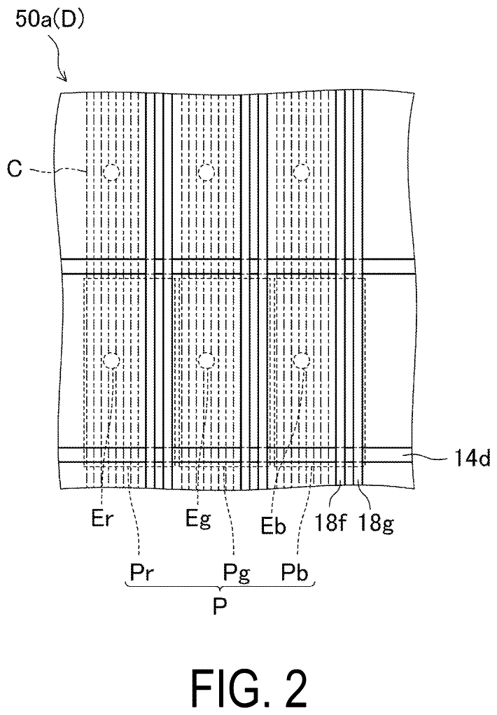

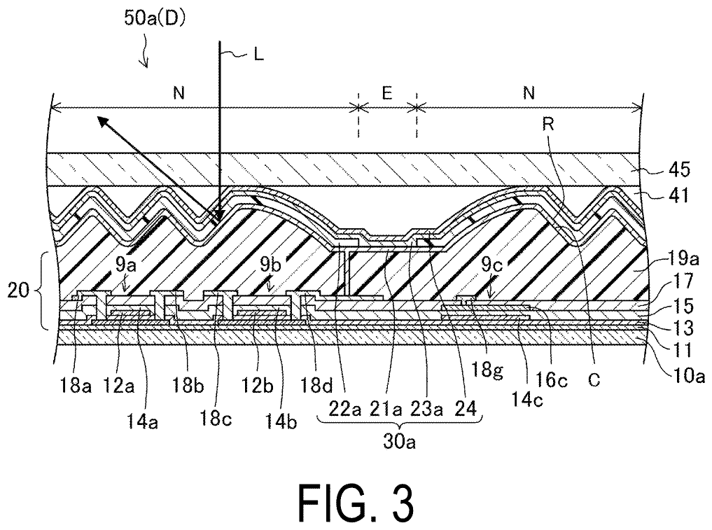

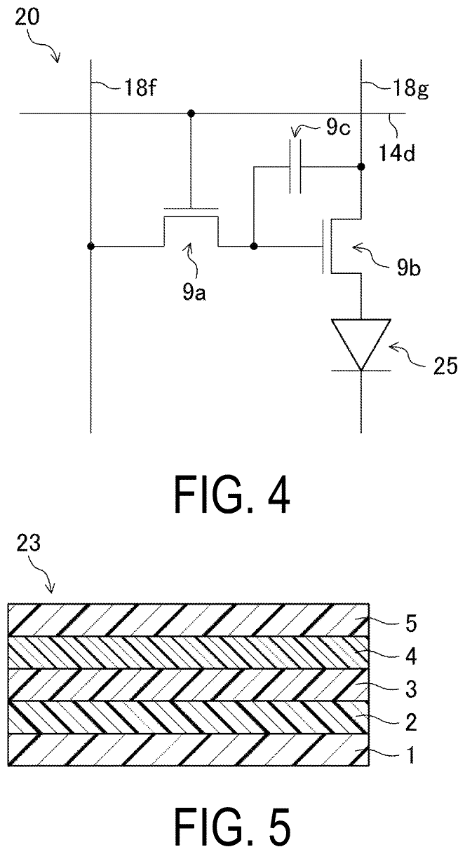

FIGS. 1 to 5 illustrate a first embodiment of a display device according to the disclosure. Further, in the present embodiment and the following second to sixth embodiments, a display device including a quantum-dot light emitting diode (QLED) is exemplified as a display device including a light-emitting element layer. Here, FIG. 1 is a plan view illustrating a schematic configuration of a display device 50a according to the present embodiment. In addition, FIG. 2 is a plan view illustrating a detailed configuration of a display region D in the display device 50a. In addition, FIG. 3 is a cross-sectional view of the display region D of the display device 50a. In addition, FIG. 4 is an equivalent circuit diagram of a TFT layer 20 constituting the display device 50a. In addition, FIG. 5 is a cross-sectional view illustrating a light-emitting function layer 23 constituting the display device 50a.

The display device 50a includes, for example, the display region D provided in a rectangular shape and used to display images, and a frame region F provided in a frame-like shape surrounding the display region D as illustrated in FIG. 1. Further, although the display region D having a rectangular shaped is exemplified in the present embodiment, the rectangular shape includes, for example, a substantially rectangular shape such as a shape whose sides are arc-shaped, a shape whose corners are arc-shaped, and a shape in which some of the sides are notched.

A plurality of red subpixels Pr, green subpixels Pg, and blue subpixels Pb are arrayed in a matrix shape in the display region D as illustrated in FIG. 2. In addition, for example, the red subpixels Pr including a red light-emitting region Er for displaying red, the green subpixels Pg including a green light-emitting region Eg for displaying green, and the blue subpixels Pb including a blue light-emitting region Eb for displaying blue are provided adjacent to each other in the display region D as illustrated in FIG. 2. Further, one pixel P is formed by three adjacent subpixels including a red subpixel Pr, a green subpixel Pg, and a blue subpixel Pb in the display region D as illustrated in FIG. 2.

A terminal portion T is provided at the lower end portion of the frame region F in FIG. 1. Further, in the frame region F, a bendable bending portion B that can bend 180° (in a U-shape) with the horizontal direction of the drawing as a bending axis is provided between the display region D and the terminal portion T to extend in one direction (the horizontal direction in the drawing) as illustrated in FIG. 1.

The display device 50a includes a glass substrate layer 10a provided as a base substrate layer, a thin film transistor (hereinafter, also referred to as a TFT) layer 20 provided on the glass substrate layer 10a, a light-emitting element layer 30a provided on the TFT layer 20, and a cover glass layer 45 provided on the light-emitting element layer 30a via an air layer 41 as illustrated in FIG. 3.

The glass substrate layer 10a is formed of, for example, a glass substrate or the like having a thickness of about 0.1 mm to 0.5 mm.

The TFT layer 20 includes a base coat film 11 provided on the glass substrate layer 10a, a plurality of first TFTs 9a, a plurality of second TFTs 9b, and a plurality of capacitors 9c provided on the base coat film 11, and a flattening film 19a provided as a resin film on each of the first TFTs 9a, each of the second TFTs 9b, and each of the capacitors 9c as illustrated in FIG. 3. Here, a plurality of gate lines 14d are provided in the TFT layer 20 to extend in parallel to each other in the horizontal direction in the drawings as illustrated in FIG. 2 and FIG. 4. In addition, a plurality of source lines 18f are provided in the TFT layer 20 to extend in parallel to each other in the vertical direction in the drawings as illustrated in FIG. 2 and FIG. 4. In addition, a plurality of power source lines 18g are provided in the TFT layer 20 to extend in parallel to each other in the vertical direction in the drawings as illustrated in FIG. 2 and FIG. 4. Further, each of the power source lines 18g is provided adjacent to one of the source lines 18f as illustrated in FIG. 2. In addition, a first TFT 9a, a second TFT 9b, and a capacitor 9c are provided in each of the red subpixel Pr, green subpixel Pg, and blue subpixel Pb in the TFT layer 20 as illustrated in FIG. 4.

The base coat film 11, a gate insulating film 13, a first interlayer insulating film 15, and a second interlayer insulating film 17 to be described below are composed of, for example, a single-layer film or a layered film of an inorganic insulating film of silicon nitride, silicon oxide, silicon oxynitride, or the like.

The first TFT 9a is electrically connected to the corresponding gate line 14d and source line 18f in each of the red subpixels Pr, the green subpixels Pg, and the blue subpixels Pb as illustrated in FIG. 4. In addition, the first TFT 9a includes a semiconductor layer 12a, a gate insulating film 13, a gate electrode 14a, a first interlayer insulating film 15, a second interlayer insulating film 17, and a source electrode 18a and a drain electrode 18b, which are provided in order on the base coat film 11 as illustrated in FIG. 3. Here, the semiconductor layer 12a is provided in an island shape on the base coat film 11 as illustrated in FIG. 3, and has, for example, a channel region, a source region, and a drain region. In addition, the gate insulating film 13 is provided to cover the semiconductor layer 12a as illustrated in FIG. 3. In addition, the gate electrode 14a is provided on the gate insulating film 13 to overlap the channel region of the semiconductor layer 12a as illustrated in FIG. 3. In addition, the first interlayer insulating film 15 and the second interlayer insulating film 17 are provided in order, covering the gate electrode 14a as illustrated in FIG. 3. In addition, the source electrode 18a and the drain electrode 18b are separated from each other on the second interlayer insulating film 17 as illustrated in FIG. 3. In addition, the source electrode 18a and the drain electrode 18b are electrically connected to the source region and the drain region of the semiconductor layer 12a, respectively, via each of contact holes formed in the layered film including the gate insulating film 13, the first interlayer insulating film 15, and the second interlayer insulating film 17 as illustrated in FIG. 3.

The second TFT 9b is electrically connected to the corresponding first TFT 9a and power source line 18g in each of the red subpixels Pr, the green subpixels Pg, and the blue subpixels Pb as illustrated in FIG. 4. In addition, the first TFT 9b includes a semiconductor layer 12b, the gate insulating film 13, a gate electrode 14b, the first interlayer insulating film 15, the second interlayer insulating film 17, and a source electrode 18c and a drain electrode 18d, which are provided in order on the base coat film 11 as illustrated in FIG. 3. Here, the semiconductor layer 12b is provided in an island shape on the base coat film 11 as illustrated in FIG. 3, and has, for example, a channel region, a source region, and a drain region. In addition, the gate insulating film 13 is provided to cover the semiconductor layer 12b as illustrated in FIG. 3. In addition, the gate electrode 14b is provided on the gate insulating film 13 to overlap the channel region of the semiconductor layer 12b as illustrated in FIG. 3. In addition, the first interlayer insulating film 15 and the second interlayer insulating film 17 are provided in order, covering the gate electrode 14b as illustrated in FIG. 3. In addition, the source electrode 18c and the drain electrode 18d are separated from each other on the second interlayer insulating film 17 as illustrated in FIG. 3. In addition, the source electrode 18c and the drain electrode 18d are electrically connected to the source region and the drain region of the semiconductor layer 12b, respectively, via each of the contact holes formed in the layered film including the gate insulating film 13, the first interlayer insulating film 15, and the second interlayer insulating film 17 as illustrated in FIG. 3.

Further, although the top-gate type first TFT 9a and second TFT 9b are exemplified in the present embodiment, the first TFT 9a and the second TFT 9b may be bottom-gate type TFTs.

The capacitor 9c is electrically connected to the corresponding first TFT 9a and power source line 18g in each of the red subpixels Pr, the green subpixels Pg, and the blue subpixels Pb as illustrated in FIG. 4. Here, the capacitor 9c includes a lower conductive layer 14c formed in the same layer using the same material as the gate line 14d and the gate electrodes 14a and 14b, the first interlayer insulating film 15 provided to cover the lower conductive layer 14c, and an upper conductive layer 16c provided on the first interlayer insulating film 15 to overlap the lower conductive layer 14c as illustrated in FIG. 3. Further, the upper conductive layer 16c is electrically connected to the power source line 18g via a contact hole formed in the second interlayer insulating film 17 as illustrated in FIG. 3.

The flattening film 19a has a flat surface in the light-emitting regions E (see Er, Eg, and Eb in FIG. 2) of the red subpixels Pr, the green subpixels Pg, and the blue subpixels Pb, has a surface in which a plurality of recessed portions C are formed extending in parallel to each other in the non-light-emitting regions N of each of the red subpixels Pr, the green subpixels Pg, and the blue subpixels Pb as illustrated in FIG. 3, and is provided as a resin film made of an organic resin material, for example, a polyimide resin. Further, in each of the red subpixels Pr, the green subpixels Pg, and the blue subpixels Pb, the light-emitting regions E (Er, Eg, and Eb) correspond to a portion of pixel electrodes 21a exposed from an edge cover 22a to be described below, and the non-light-emitting regions N correspond to a portion of the pixel electrodes 21a overlapping the edge cover 22a as illustrated in FIG. 3. Here, a pitch of the plurality of recessed portions C is approximately from 5 μm to 20 μm, for example. In addition, each of the recessed portions C has a V-shaped cross section, and an inclined surface thereof is inclined at, for example, about 15° to 40° or about 50° to 80° with respect to the surface of the glass substrate layer 10a as illustrated in FIG. 3. In addition, each of the recessed portions C is provided along the longer sides of each of the red subpixels Pr, the green subpixels Pg, and the blue subpixels Pb each having a rectangular shape in a plan view as illustrated in FIG. 2. In addition, a diameter of the light-emitting regions E (Er, Eg, and Eb) is, for example, about 10 μm to 20 μm.

The light-emitting element layer 30a includes a plurality of pixel electrodes 21a, a common edge cover 22a, a plurality of light-emitting function layers 23a, and a common electrode 24 that are provided in order corresponding to a plurality of red subpixels Pr, green subpixels Pg, and blue subpixels Pb as illustrated in FIG. 3.

Each pixel electrode 21a is electrically connected to the drain electrode 18d of the second TFT 9b of each red subpixel Pr, green subpixel Pg, and blue subpixel Pb via a contact hole formed in the flattening film 19a as illustrated in FIG. 3. In addition, the pixel electrodes 21a have a function of injecting holes (positive holes) into the light-emitting function layers 23a. In addition, the pixel electrodes 21a are preferably formed of a material having a high work function for the purpose of improving the efficiency of hole injection into the light-emitting function layers 23a. Here, examples of materials constituting the pixel electrodes 21a include a metal material such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), tin (Sn) and the like. Examples of materials constituting the pixel electrodes 21a also include alloys, such as an alloy of astatine (At)-astatine oxide (AtO₂). Furthermore, examples of materials constituting the pixel electrodes 21a include electrically conductive oxides such as tin oxide (SnO), zinc oxide (ZnO), indium tin oxide (ITO), and indium zinc oxide (IZO). The pixel electrodes 21a may also be formed by layering a plurality of layers formed of any of the materials described above. Further, examples of compound materials having a high work function include indium tin oxide (ITO) and indium zinc oxide (IZO). To be more specific, the pixel electrodes 21a are formed of, for example, a layered film in which an ITO film having a thickness of about 10 nm, a silver film having a thickness of about 100 nm, and an ITO film having a thickness of about 10 nm are layered in order, and have light reflectivity. In addition, in each of the red subpixels Pr, the green subpixels Pg, and the blue subpixels Pb, the pixel electrodes 21a have a reflective surface that is flat due to the flat surface of the flattening film 19a in the light-emitting regions E (Er, Eg, and Eb), and a reflective surface R having an uneven shape due to the recessed portions C on the surface of the flattening film 19a is provided in the non-light-emitting regions N as illustrated in FIG. 3. Further, although the structure in which the pixel electrodes 21a are electrically connected to the drain electrodes 18d of the second TFTs 9b is exemplified in the present embodiment, other pixel electrodes may be provided as relay electrodes between the pixel electrodes 21a and the drain electrodes 18d of the second TFTs 9b.

The edge cover 22a is provided in a lattice pattern to cover a peripheral edge portion of each pixel electrode 21a. Here, examples of materials constituting the edge cover 22a include a photosensitive resin such as a polyimide resin, an acrylic resin, a polysiloxane resin, and an ovolac resin.

Each light-emitting function layer 23 includes a hole injection layer 1, a hole transport layer 2, a quantum dot light-emitting layer 3, an electron transport layer 4, and an electron injection layer 5 that are provided in order on the pixel electrodes 21a as illustrated in FIG. 5.

The hole injection layer 1 is also called an anode electrode buffer layer, and has a function of making an energy level of the pixel electrodes 21a close to that of the light-emitting function layers 23a to thereby improve the efficiency of hole injection from the pixel electrodes 21a into the light-emitting function layers 23a. Here, examples of material constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, stilbene derivatives, thiophene derivatives, metal oxides such as nickel oxide (NiO) nanoparticles, and the like.

The hole transport layer 2 has a function of improving the efficiency in hole transport from the pixel electrodes 21a to the light-emitting function layers 23a. Here, examples of material constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The quantum dot light-emitting layer 3 is a region where holes and electrons are injected from the pixel electrodes 21a and the common electrode 24, respectively, and the holes and the electrons recombine when a voltage is applied via the pixel electrodes 21a and the common electrode 24. Here, the quantum dot light-emitting layer 3 contains quantum dots (semiconductor nanoparticles) as a light-emitting material, and has a luminescence peak in the visible light range. In addition, examples of material constituting the quantum dot light-emitting layer 3 may include, for example, a semiconductor material formed of an element of at least one type selected from the group consisting of cadmium (Cd), sulfur (S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg). Furthermore, the quantum dot light-emitting layer 3 may be of a two-component core type, a three-component core type, a four-component core type, a core-shell type, or a core multi-shell type.

The electron transport layer 4 has a function of causing electrons to migrate to the quantum dot light-emitting layer 3 efficiently. Here, examples of materials constituting the electron transport layer 4 include, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 has a function of making an energy level of the common electrode 24 close to that of the light-emitting function layers 23a to thereby improve the efficiency in electron injection into the light-emitting function layer 23a from the common electrode 24, and thus can lower the drive voltage of the light-emitting elements due to this function. Further, the electron injection layer 5 is also called a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), strontium oxide (SrO), zinc oxide (ZnO), magnesium zinc oxide (MgZnO), and the like.

The common electrode 24 is provided to cover the light-emitting function layers 23a of each of the red subpixels Pr, the green subpixels Pg, and the blue subpixels Pb as illustrated in FIG. 3. In addition, the common electrode 24 has a function of injecting electrons into the light-emitting function layers 23a. In addition, the common electrode 24 is preferably made of a material with a low work function to improve the efficiency of electron injection into the light-emitting function layers 23a. Here, examples of materials constituting the common electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), lithium fluoride (LiF), and the like. In addition, the common electrode 24 may be formed of an alloy, such as alloys of magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al), for example. In addition, the common electrode 24 may be formed of electrically conductive oxides, for example, tin oxide (SnO), zinc oxide (ZnO), indium tin oxide (ITO), indium zinc oxide (IZO), aluminum zinc oxide (AZO), and the like. In addition, the common electrode 24 may be formed by layering a plurality of layers formed of any of the materials described above. Further, examples of materials having a low work function include magnesium (Mg), lithium (Li), lithium fluoride (LiF), alloys of magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al), and the like.

The cover glass layer 45 is formed of, for example, a glass substrate or the like having a thickness of about 0.1 mm to 0.5 mm.

The display device 50a described above is configured such that, in each of the red subpixels Pr, the green subpixels Pg, and the blue subpixels Pb, a gate signal is input to the first TFT 9a via the gate line 14d to thereby turn on the first TFT 9a, a voltage corresponding to a source signal is written into the gate electrode 14b of the second TFT 9b and the capacitor 9c via the source line 18f, and a current from the power source line 18g defined based on the gate voltage of the second TFT 9b is supplied to the light-emitting function layers 23a, and thereby, the quantum dot light-emitting layer 3 of the light-emitting function layers 23a emits light to display an image. Further, even when the first TFT 9a is off in the display device 50a, the gate voltage of the second TFT 9b is held by the capacitor 9c, and thus light emission by the quantum dot light-emitting layer 3 is maintained until a gate signal for the next frame is input.

Next, a manufacturing method for the display device 50a according to the present embodiment will be described. Further, the manufacturing method for the display device 50a according to the present embodiment includes a TFT layer forming step, a light-emitting element layer forming step, and a cover glass attaching step.

### TFT Layer Forming Step

For example, by using a known method, the TFT layer 20 is formed on a surface of the glass substrate layer 10a by forming the base coat film 11, the first TFT 9a, the second TFT 9b, the capacitor 9c, and the flattening film 19a. Further, when the flattening film 19a is formed, after a photosensitive polyimide resin is coated by using, for example, a spin coating method or a slit coating method, the coated film is pre-baked, exposed, developed, and post-baked by using a half-tone mask, a gray-tone mask, or the like, and thereby the recessed portions C in a predetermined shape are formed on the surface of the flattening film 19a.

### Light-Emitting Element Layer Forming Step

The light-emitting element layer 30a is formed by forming the pixel electrodes 21a, the edge cover 22a, the light-emitting function layers 23a (the hole injection layer 1, the hole transport layer 2, the quantum dot light-emitting layer 3, the electron transport layer 4, and the electron injection layer 5), and the common electrode 24 on the flattening film 19a of the TFT layer 20 formed in the TFT layer forming step by using a known method.

### Cover Glass Attaching Step

The cover glass layer 45 is attached onto the light-emitting element layer 30a formed in the light-emitting element layer forming step.

The display device 50a of the present embodiment can be manufactured as described above.

According to the display device 50a of the present embodiment as described above, in the non-light-emitting regions N of each of the red subpixels Pr, the green subpixels Pg, and the blue subpixels Pb, the pixel electrodes 21a are provided with the reflective surface R having an uneven shape due to the plurality of recessed portions C formed on the surface of the flattening film 19a. For this reason, external light L is reflected in a direction different from the direction in which light is incident on the reflective surface R in the non-light-emitting regions N, and thus the reflected light visually recognized by the user is reduced. Accordingly, since the degradation of display quality caused by the reflection of the external light L is reduced in the display device 50a, the degradation of the display quality caused by reflection of external light L can be reduced without using a circular polarizer.

In addition, according to the display device 50a of the present embodiment, since the plurality of recessed portions formed on the surface of the flattening film 19a are provided along the longer sides of each of the red subpixels Pr, the green subpixels Pg, and the blue subpixels Pb, the external light L from the direction along the shorter sides of each of the red subpixels Pr, the green subpixels Pg, and the blue subpixels Pb can be effectively reflected on the reflective surface R in the non-light-emitting regions N.

### Second Embodiment

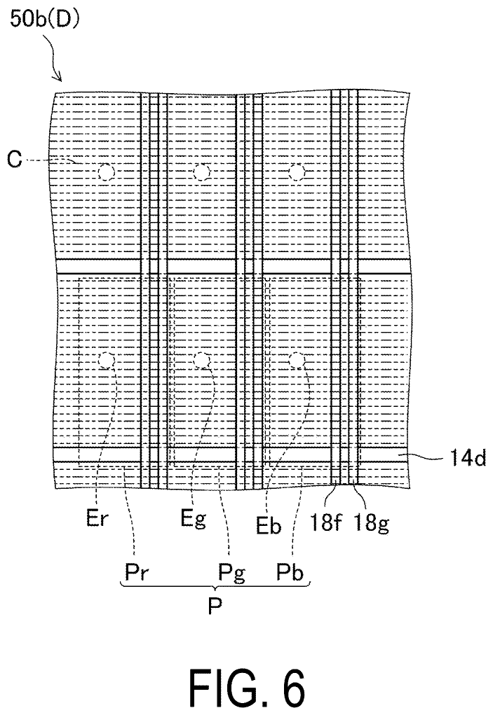

FIG. 6 illustrates a second embodiment of the display device according to the disclosure. Here, FIG. 6 is a plan view illustrating a detailed configuration of a display region D of a display device 50b according to the present embodiment, and is a view corresponding to FIG. 2 described in the above-described first embodiment. Further, in each of the following embodiments, the same portions as those in FIG. 1 to FIG. 5 are denoted by the same reference signs, and detailed description of these portions are omitted.

Although the display device 50a in which the plurality of recessed portions C are provided along the longer sides of each of the subpixels has been exemplified in the first embodiment described above, the display device 50b in which a plurality of recessed portions C are provided along the shorter sides of each of the subpixels is exemplified in the present embodiment.

The display device 50b has substantially the same configuration as that of the display device 50a according to the first embodiment except that a plurality of recessed portions formed on the surface of the flattening film 19a are provided along the shorter sides of each of the red subpixels Pr, the green subpixels Pg, and the blue subpixels Pb.

Similarly to the display device 50a of the first embodiment, the display device 50b described above is configured to display an image by causing the quantum dot light-emitting layer 3 of the light-emitting function layer 23a to emit light as required, via the first TFT 9a and the second TFT 9b in each of the red subpixels Pr, the green subpixels Pg, and the blue subpixels Pb.

The display device 50b of the present embodiment can be manufactured by modifying a pattern shape of the flattening film 19a in the manufacturing method for the display device 50a of the above-described first embodiment.

According to the display device 50b of the present embodiment as described above, in the non-light-emitting region N of each of the red subpixels Pr, the green subpixels Pg, and the blue subpixels Pb, the pixel electrode 21a is provided with a reflective surface R having an uneven shape due to the plurality of recessed portions C formed on the surface of the flattening film 19a. For this reason, external light L is reflected in a direction different from the direction in which light is incident on the reflective surface R in the non-light-emitting regions N, and thus the reflected light visually recognized by the user is reduced. Accordingly, since the degradation of display quality caused by the reflection of external light L is reduced in the display device 50b, the degradation of the display quality caused by reflection of external light L can be reduced without using a circular polarizer.

In addition, according to the display device 50b of the present embodiment, since the plurality of recessed portions formed on the surface of the flattening film 19a are provided along the shorter sides of each of the red subpixels Pr, the green subpixels Pg, and the blue subpixels Pb, external light L from the direction along the longer sides of each of the red subpixels Pr, the green subpixels Pg, and the blue subpixels Pb can be effectively reflected on the reflective surface R in the non-light-emitting region N.

### Third Embodiment

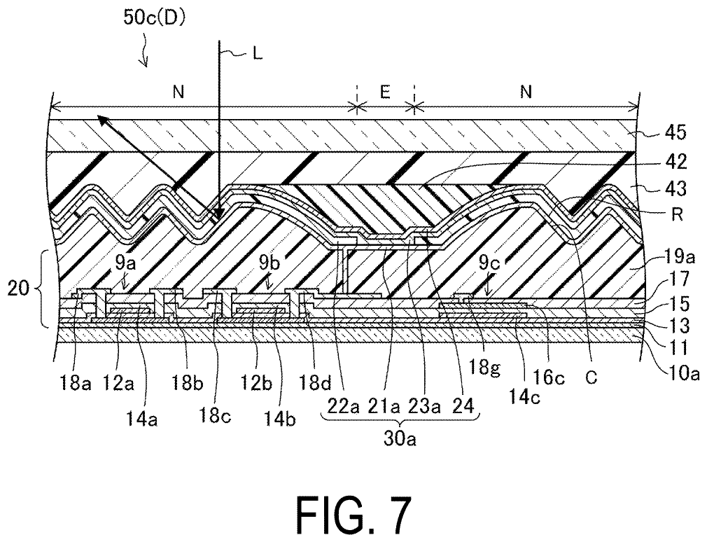

FIG. 7 illustrates a third embodiment of the display device according to the disclosure. Here, FIG. 7 is a cross-sectional view of a display region D of a display device 50c according to the present embodiment, and is a view corresponding to FIG. 3 described in the above-described first embodiment.

Although the display device 50a in which the air layer 41 is provided between the light-emitting element layer 30a and the cover glass layer 45 is illustrated in the first embodiment, the display device 50c in which a high refractive index material layer 42 and a low refractive index material layer 43 are provided between the light-emitting element layer 30a and the cover glass layer 45 is illustrated in the present embodiment.

The display device 50c includes a display region D and a frame region F provided in a frame-like shape around the display region D, similarly to the display device 50a of the first embodiment described above.

The display device 50c includes a glass substrate layer 10a provided as a base substrate layer, a TFT layer 20 provided on the glass substrate layer 10a, a light-emitting element layer 30a provided on the TFT layer 20, and a cover glass layer 45 provided on the light-emitting element layer 30a via a layered body including a high refractive index material layer 42 and a low refractive index material layer 43 as illustrated in FIG. 7.

The high refractive index material layer 42 is provided in the light-emitting region E of each of red subpixels Pr, green subpixels Pg, and blue subpixels Pb (see Er, Eg, and Eb in FIG. 2) and around thereof as shown in FIG. 7. Here, the high refractive index material layer 42 is formed of, for example, a material having a relatively high refractive index (refractive index of about 1.7 to 2.0) such as an acrylic resin containing zirconia-based fine particles, or the like.

The low refractive index material layer 43 is provided to cover the high refractive index material layer 42 in each of the red subpixels Pr, the green subpixels Pg, and the blue subpixels Pb as illustrated in FIG. 7. Here, the low refractive index material layer 43 is formed of, for example, a material having a relatively low refractive index (refractive index of about 1.2 to 1.4) such as an acrylic resin containing silica-based fine particles, or the like. In addition, the low refractive index material layer 43 may be formed of, for example, a gas such as nitrogen containing no moisture or a vacuum layer.

According to the layered body including the high refractive index material layer 42 and the low refractive index material layer 43 described above, light emitted from the quantum dot light-emitting layer 3 of the light-emitting function layer 23a is incident on the high refractive index material layer 42 and then radiated through the low refractive index material layer 43 and the cover glass layer 45, or is totally reflected at the interface with the low refractive index material layer 43 and reflected again on the pixel electrode 21a to change its direction, passes through the interface with the low refractive index material layer 43, and is radiated through the low refractive index material layer 43 and the cover glass layer 45, and thus the light emitted from the quantum dot light-emitting layer 3 can be extracted to the outside with high efficiency.

Similarly to the display device 50a of the first embodiment, the display device 50c described above is configured to display an image by causing the quantum dot light-emitting layer 3 of the light-emitting function layer 23a to emit light as required, via the first TFT 9a and the second TFT 9b in each of the red subpixels Pr, the green subpixels Pg, and the blue subpixels Pb.

The display device 50c of the present embodiment can be manufactured by forming the high refractive index material layer 42 and the low refractive index material layer 43 by using, for example, an ink-jet method, a slit coating method, or the like before attaching the cover glass layer 45 onto the light-emitting element layer 30a in the manufacturing method for the display device 50a of the first embodiment.

According to the display device 50c of the present embodiment as described above, in the non-light-emitting region N of each of the red subpixels Pr, the green subpixels Pg, and the blue subpixels Pb, the pixel electrode 21a is provided with the reflective surface R having an uneven shape due to the plurality of recessed portions C formed on the surface of the flattening film 19a. For this reason, external light L is reflected in a direction different from the direction in which light is incident on the reflective surface R in the non-light-emitting regions N, and thus the reflected light visually recognized by the user is reduced. Accordingly, since the degradation of display quality caused by the reflection of external light L is reduced in the display device 50c, the degradation of the display quality caused by reflection of the external light L can be reduced without using a circular polarizer.

In addition, according to the display device 50c of the present embodiment, since the plurality of recessed portions formed on the surface of the flattening film 19a are provided along the longer sides of each of the red subpixels Pr, the green subpixels Pg, and the blue subpixels Pb, external light L from the direction along the shorter sides of each of the red subpixels Pr, the green subpixels Pg, and the blue subpixels Pb can be effectively reflected on the reflective surface R in the non-light-emitting region N.

### Fourth Embodiment

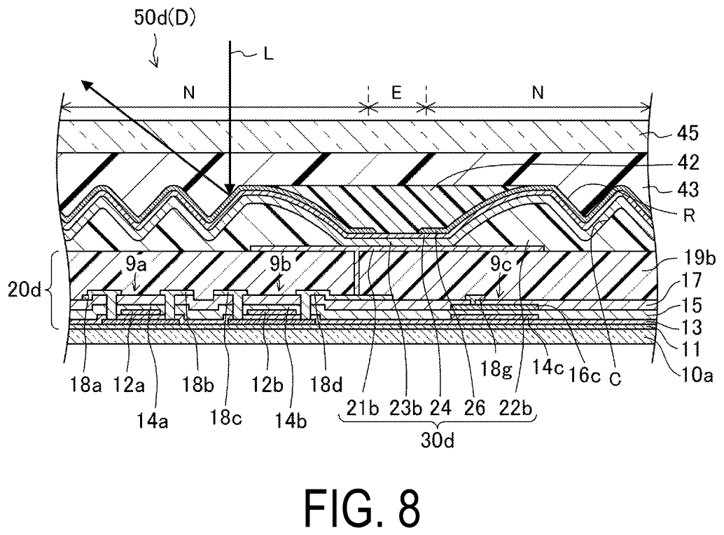

FIG. 8 illustrates a fourth embodiment of the display device according to the disclosure. Here, FIG. 8 is a cross-sectional view of a display region D of a display device 50d according to the present embodiment, and is a view corresponding to FIG. 3 described in the above-described first embodiment.

Although the display device 50a in which the reflective surface R is provided on the surface of the pixel electrode 21a is exemplified in the first embodiment described above, in the present embodiment, the display device 50d in which the reflective surface R is provided on the surface of a reflective film 26 is exemplified.

The display device 50d includes a display region D and a frame region F provided in a frame-like shape around the display region D, similarly to the display device 50a of the first embodiment described above.

The display device 50d includes a glass substrate layer 10a provided as a base substrate layer, a TFT layer 20d provided on the glass substrate layer 10a, a light-emitting element layer 30d provided on the TFT layer 20d, and a cover glass layer 45 provided on the light-emitting element layer 30d via a layered body including a high refractive index material layer 42 and a low refractive index material layer 43 as illustrated in FIG. 8.

The TFT layer 20d includes a base coat film 11 provided on the glass substrate layer 10a, a plurality of first TFTs 9a, a plurality of second TFTs 9b, and a plurality of capacitors 9c provided on the base coat film 11, and a flattening film 19b provided on each of the first TFTs 9a, each of the second TFTs 9b, and each of the capacitors 9c as illustrated in FIG. 8. Here, similarly to the TFT layer 20 of the first embodiment described above, a plurality of gate lines 14d, a plurality of source lines 18f, and a plurality of power source lines 18g are provided in the TFT layer 20d. In addition, the first TFTs 9a, a second TFTs 9b, and the capacitors 9c are provided in each of the red subpixels Pr, the green subpixels Pg, and the blue subpixels Pb in the TFT layer 20d as illustrated in FIG. 8.

The flattening film 19b has a flat surface in the display region D as illustrated in FIG. 8, and is provided as a resin film formed of an organic resin material such as a polyimide resin, for example.

The light-emitting element layer 30d includes a plurality of pixel electrodes 21b, a common edge cover 22b, a plurality of light-emitting function layers 23b, and a common electrode 24 and a common reflective film 26 that are provided in order corresponding to a plurality of red subpixels Pr, green subpixels Pg, and blue subpixels Pb as illustrated in FIG. 8.

The pixel electrodes 21b are electrically connected to the drain electrodes 18d of the second TFTs 9b of each of the red subpixels Pr, the green subpixels Pg, and the blue subpixels Pb via a contact hole formed in the flattening film 19b as illustrated in FIG. 8. In addition, the pixel electrodes 21b have a function of injecting holes (positive holes) into the light-emitting function layers 23b. In addition, the pixel electrodes 21b are preferably formed of a material having a high work function for the purpose of improving the efficiency of hole injection into the light-emitting function layers 23b. Here, the material constituting the pixel electrodes 21b is substantially the same as the material constituting the pixel electrodes 21a of the first embodiment.

The edge cover 22b is provided in a lattice pattern to cover a peripheral edge portion of each pixel electrode 21b. Here, examples of a material constituting the edge cover 22b include a photosensitive resin such as a polyimide resin, an acrylic resin, a polysiloxane resin, and a novolac resin. In addition, a plurality of recessed portions C are provided on a surface of the edge cover 22b to extend in parallel to each other in the non-light-emitting region N of each of the red subpixels Pr, the green subpixels Pg, and the blue subpixels Pb as illustrated in FIG. 8. Further, a pitch of the plurality of recessed portions C is approximately from 5 μm to 20 μm, for example. In addition, each of the recessed portions C has a V-shaped cross section, and an inclined surface thereof is inclined at, for example, about 15° to 40° or about 50° to 80° with respect to the surface of the glass substrate layer 10a as illustrated in FIG. 8. In addition, each of the recessed portions C is provided along the longer sides or shorter sides of each of the red subpixels Pr, the green subpixels Pg, and the blue subpixels Pb each having a rectangular shape in a plan view.

The light-emitting function layer 23b includes a hole injection layer 1, a hole transport layer 2, a quantum dot light-emitting layer 3, an electron transport layer 4, and an electron injection layer 5 that are provided in order on the pixel electrodes 21b, similarly to the light-emitting function layer 23a of the above-described first embodiment.

The reflective film 26 is provided in a lattice pattern to overlap a peripheral edge portion of each of the pixel electrodes 21b as illustrated in FIG. 8. Here, the reflective film 26 is constituted by a layered film of, for example, a silver (Ag) film as a lower layer having a thickness of approximately 100 nm and an indium tin oxide (ITO) film as an upper layer having a thickness of approximately 10 nm. In addition, a portion in each of the red subpixels Pr, the green subpixels Pg, and the blue subpixels Pb, the portion being exposed from the reflective film 26, constitutes a light-emitting region E (Er, Eg, or Eb), and a portion thereof overlapping the reflective film 26 constitutes a non-light-emitting region as illustrated in FIG. 8. In addition, the reflective film 26 is provided with a reflective surface R having an uneven shape due to the recessed portions C on the surfaces of the edge covers 22b in the non-light-emitting region N of each of the red subpixels Pr, the green subpixels Pg, and the blue subpixels Pb as illustrated in FIG. 8.

Similarly to the display device 50a of the first embodiment, the display device 50d described above is configured to display an image by causing the quantum dot light-emitting layer 3 of the light-emitting function layer 23b to emit light as required, via the first TFTs 9a and the second TFTs 9b in each of the red subpixels Pr, the green subpixels Pg, and the blue subpixels Pb.

The display device 50d of the present embodiment can be manufactured in the manufacturing method for the display device 50a of the first embodiment by forming the base coat film 11, the first TFTs 9a, the second TFTs 9b, the capacitors 9c, and the flattening film 19b by using a known method to form the TFT layer 20d, and then forming the pixel electrodes 21b, the edge cover 22b, the light-emitting function layer 23b, the common electrode 24, and the reflective film 26 to form the light-emitting element layer 30d by using a known method, and then forming the high refractive index material layer 42 and the low refractive index material layer 43 by using, for example, an ink-jet method or a slit coating method before attaching the cover glass layer 45 onto the light-emitting element layer 30b. Further, when the edge cover 22b is formed, after a photosensitive polyimide resin is coated by using, for example, a spin coating method or a slit coating method, the coated film is pre-baked, exposed, developed, and post-baked by using a half-tone mask, a gray-tone mask, or the like, and thereby the recessed portions C in a predetermined shape are formed on the surface of the edge cover 22b.

According to the display device 50d of the present embodiment as described above, in the non-light-emitting region N of each of the red subpixels Pr, the green subpixels Pg, and the blue subpixels Pb, the reflective film 26 is provided with the reflective surface R having an uneven shape due to the plurality of recessed portions C formed on the surface of the edge cover 22b. For this reason, external light L is reflected in a direction different from the direction in which light is incident on the reflective surface R in the non-light-emitting regions N, and thus the reflected light visually recognized by the user is reduced. Accordingly, since the degradation of display quality caused by the reflection of the external light L is reduced in the display device 50d, the degradation of the display quality caused by reflection of the external light L can be reduced without using a circular polarizer.

### Fifth Embodiment

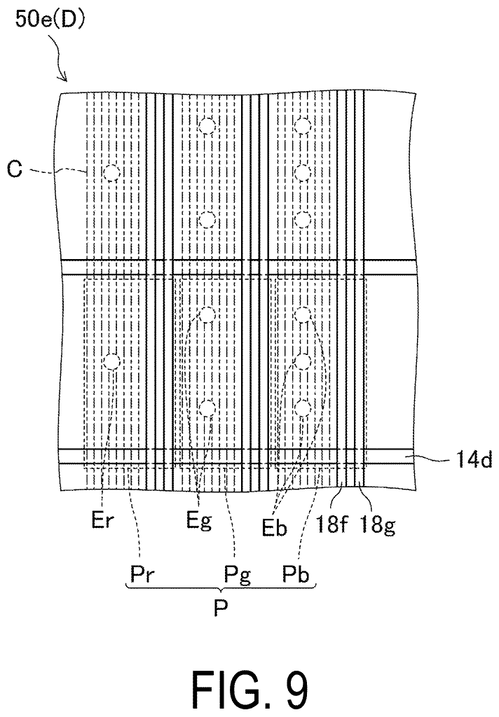

FIG. 9 illustrate a fifth embodiment of the display device according to the disclosure. Here, FIG. 9 is a plan view illustrating a detailed configuration of a display region D of a display device 50e according to the present embodiment, and is a view corresponding to FIG. 2 described in the above-described first embodiment.

Although the display device 50a in which one light-emitting region E is provided in each of the red subpixels Pr, the green subpixels Pg, and the blue subpixels Pb is illustrated in the first embodiment, in the present embodiment, a display device 50e in which the number of light-emitting regions E in each of the red subpixels Pr, the green subpixels Pg, and the blue subpixels Pb is set for each luminescent color is illustrated.

As illustrated in FIG. 9, the display device 50e has substantially the same configuration as the display device 50a of the first embodiment except that red subpixels Pr each having one red light-emitting region Er, green subpixels Pg each having two green light-emitting regions Eg, and blue subpixels Pb each having three blue light-emitting regions Eb are provided adjacent to each other in the display region D. Here, the number of blue light-emitting regions Eb in the blue subpixel Pb is larger than the number of green light-emitting regions Eg in the green subpixel Pg, and the number of red light-emitting regions Er in the red subpixel Pr is smaller than the number of green light-emitting regions Eg in the green subpixel Pg.

Similarly to the display device 50a of the first embodiment, the display device 50e described above is configured to display an image by causing the quantum dot light-emitting layer 3 of the light-emitting function layer 23a to emit light as required, via the first TFTs 9a and the second TFTs 9b in each of the red subpixels Pr, the green subpixels Pg, and the blue subpixels Pb.

The display device 50e of the present embodiment can be manufactured by modifying pattern shapes of the flattening film 19a and the edge cover 22a in the manufacturing method for the display device 50a of the above-described first embodiment.

According to the display device 50e of the present embodiment as described above, in the non-light-emitting region N of each of the red subpixels Pr, the green subpixels Pg, and the blue subpixels Pb, the pixel electrode 21a is provided with the reflective surface R having an uneven shape due to the plurality of recessed portions C formed on the surface of the flattening film 19a. For this reason, external light L is reflected in a direction different from the direction in which light is incident on the reflective surface R in the non-light-emitting region N, and thus the reflected light visually recognized by the user is reduced. Accordingly, since the degradation of display quality caused by the reflection of the external light L is reduced in the display device 50e, the degradation of the display quality caused by reflection of the external light L can be reduced without using a circular polarizer.

In addition, according to the display device 50e of the present embodiment, since the plurality of recessed portions formed on the surface of the flattening film 19a are provided along the longer sides of each of the red subpixels Pr, the green subpixels Pg, and the blue subpixels Pb, external light L from the direction along the shorter sides of each of the red subpixels Pr, the green subpixels Pg, and the blue subpixels Pb can be effectively reflected on the reflective surface R in the non-light-emitting region N.

In addition, according to the display device 50e of the present embodiment, since the number of light-emitting regions E in each of the red subpixels Pr, the green subpixels Pg, and the blue subpixels Pb is set in consideration of the luminous efficiency and the lifetime of the quantum dot light-emitting layer 3 of the light-emitting function layer 23a in each of the red subpixels Pr, the green subpixels Pg, and the blue subpixels Pb, compatibility of both the light emission amount (luminous efficiency) and the long lifetime of each of the red subpixels Pr, the green subpixels Pg, and the blue subpixels Pb can be achieved, and the display quality of the display device 50e can be improved.

### Sixth Embodiment

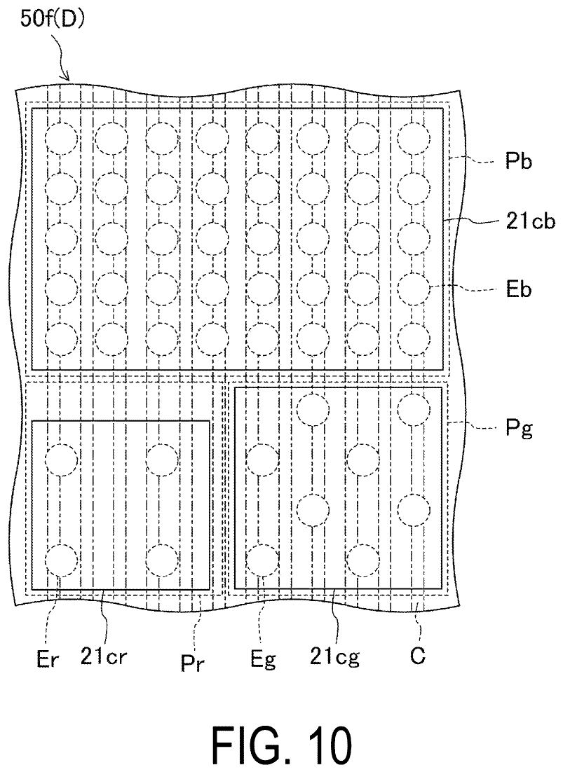

FIG. 10 illustrates a sixth embodiment of the display device according the disclosure. Here, FIG. 10 is a plan view illustrating a detailed configuration of a display region D of a display device 50f according to the present embodiment, and is a view corresponding to FIG. 2 described in the above-described first embodiment.

Although the display device 50a in which the red subpixels Pr, the green subpixels Pg, and the blue subpixels Pb are of the same size and are arranged in a stripe shape is exemplified in the first embodiment, in the present embodiment, the display device 50f in which the red subpixels Pr, the green subpixels Pg, and the blue subpixels Pb are of two sizes, large and small, and are arranged is exemplified.

As illustrated in FIG. 10, the display device 50f has substantially the same configuration as the display device 50a of the first embodiment except that a red subpixel Pr having four red light-emitting regions Er, a green subpixel Pg having eight green light-emitting regions Eg, and a blue subpixel Pb having 40 blue light-emitting regions Eb are provided in the display region D. Here, in the display device 50f, the red subpixel Pr and the green subpixel Pg each having a substantially square shape are provided side by side along the lower longer side of the blue subpixel Pb having a rectangular shape in the drawing as illustrated in FIG. 10. Further, the blue subpixel Pb is provided being larger than the red subpixel Pr and the green subpixel Pg as illustrated in FIG. 10. In addition, the number of blue light-emitting regions Eb in the blue subpixel Pb is larger than the number of green light-emitting regions Eg in the green subpixel Pg, and the number of red light-emitting regions Er in the red subpixel Pr is smaller than the number of green light-emitting regions Eg in the green subpixel Pg as illustrated in FIG. 10. In addition, a pixel electrode 21cb in the blue subpixel Pb is greater than a pixel electrode 21cg in the green subpixel Pg, and a pixel electrode 21cr in the red subpixel Pr is smaller than a pixel electrode 21cg in the green subpixel Pg as illustrated in FIG. 10.

Similarly to the display device 50a of the first embodiment, the display device 50f described above is configured to display an image by causing the quantum dot light-emitting layer 3 of the light-emitting function layer 23a to emit light as required, via the first TFTs 9a and the second TFTs 9b in each of the red subpixel Pr, the green subpixel Pg, and the blue subpixel Pb.

The display device 50f of the present embodiment can be manufactured by modifying pattern shapes of the flattening film 19a, the first electrode 21a, the edge cover 22a, and the light-emitting function layer 23a in the manufacturing method for the display device 50a of the above-described first embodiment.

According to the display device 50f of the present embodiment as described above, in the non-light-emitting region N of each of the red subpixel Pr, the green subpixel Pg, and the blue subpixel Pb, the pixel electrode 21cr, the pixel electrode 21cg, and the pixel electrode 21cb are provided with a reflective surface R having an uneven shape due to a plurality of recessed portions C formed on a surface of the flattening film 19a. For this reason, external light L is reflected in a direction different from the direction in which light is incident on the reflective surface R in the non-light-emitting region N, and thus the reflected light visually recognized by the user is reduced. Accordingly, since the degradation of display quality caused by the reflection of the external light L is reduced in the display device 50f, the degradation of the display quality caused by reflection of the external light L can be reduced without using a circular polarizer.

In addition, according to the display device 50f of the present embodiment, since the number of light-emitting regions E in each of the red subpixel Pr, the green subpixel Pg, and the blue subpixel Pb is set in consideration of the luminous efficiency and the lifetime of the quantum dot light-emitting layer 3 of the light-emitting function layer 23a in each of the red subpixel Pr, the green subpixel Pg, and the blue subpixel Pb, compatibility of both the light emission amount (luminous efficiency) and the long lifetime of each of the red subpixel Pr, the green subpixel Pg, and the blue subpixel Pb can be achieved, and the display quality of the display device 50f can be improved.

In addition, according to the display device 50f of the present embodiment, since the quantum dot light-emitting layer 3 may be patterned in a size larger than the red light-emitting regions Er, the green light-emitting regions Eg, and the blue light-emitting regions Eb in each of the red subpixel Pr, the green subpixel Pg, and the blue subpixel Pb, the manufacturing yield of the display device 50f can be improved.

### Seventh Embodiment

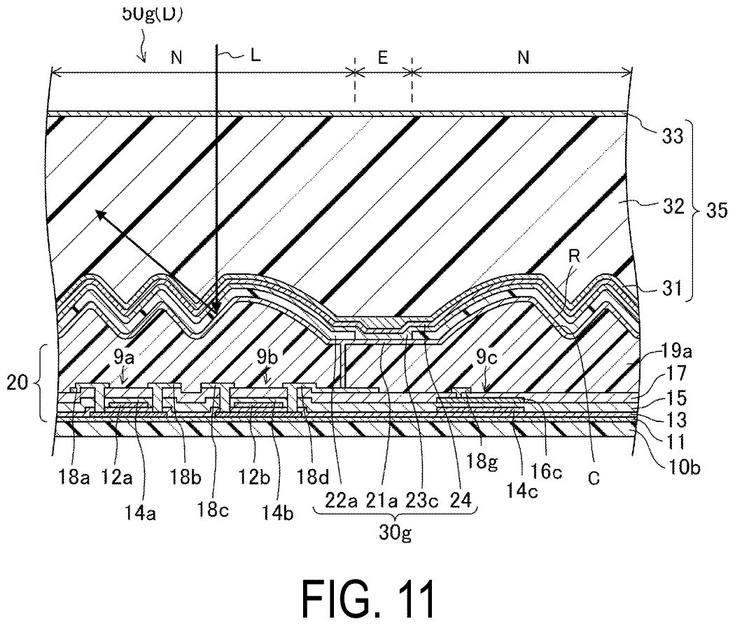

FIG. 11 illustrates a seventh embodiment of the display device according to the disclosure. Further, in the present embodiment, an organic EL display device including an organic EL element layer will be described as an example of a display device including a light-emitting element layer. Here, FIG. 11 is a cross-sectional view of a display region D of an organic EL display device 50g according to the present embodiment, and is a view corresponding to FIG. 3 described in the above-described first embodiment.

Although the display devices 50a to 50f each including quantum-dot light emitting diodes (QLEDs) are illustrated in the first to sixth embodiments, in the present embodiment, an organic EL display device 50g including an organic EL element layer 30g as a light-emitting element layer is exemplified.

The organic EL display device 50g includes a display region D and a frame region F provided in a frame-like shape around the display region D, similarly to the display device 50a of the first embodiment described above.

The organic EL display device 50g includes a resin substrate layer 10b provided as a base substrate layer, a TFT layer 20 provided on the resin substrate layer 10b, the organic EL element layer 30g provided as a light-emitting element layer on the TFT layer 20, and a sealing film 35 provided on the organic EL element layer 30g as illustrated in FIG. 11.

The resin substrate layer 10b is formed of, for example, a polyimide resin.

The organic EL element layer 30g includes a plurality of pixel electrodes 21a, a common edge cover 22a, a plurality of organic EL layers (organic electroluminescence layers and light-emitting function layers) 23c, and a common electrode 24 that are provided in order corresponding to a plurality of red subpixels Pr, green subpixels Pg, and blue subpixels Pb as illustrated in FIG. 11.

The organic EL layers 23c are provided as light-emitting function layers, and include a hole injection layer 1, a hole transport layer 2, a light-emitting layer (see the quantum dot light-emitting layer 3 in FIG. 5), an electron transport layer 4, and an electron injection layer 5 that are provided in order on the pixel electrodes 21a. Here, examples of materials constituting the light-emitting layer include metal oxinoid compounds [8-hydroxyquinoline metal complexes], naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The sealing film 35 includes a first inorganic sealing film 31 provided to cover a second electrode 24, an organic sealing film 32 provided on the first inorganic sealing film 31, and a second inorganic sealing film 33 provided to cover the organic sealing film 32, and has a function of protecting the organic EL layer 23c from moisture, oxygen, and the like as illustrated in FIG. 11. Here, the first inorganic sealing film 31 and the second inorganic sealing film 33 are formed of an inorganic material such as, for example, silicon oxide (SiO₂), aluminum oxide (Al₂O₃), silicon nitride (SiNx (where x is a positive number)) such as trisilicon tetranitride (Si₃N₄), or silicon carbonitride (SiCN). In addition, the organic sealing film 32 is formed of an organic material, for example, an acrylic resin, a polyurea resin, a parylene resin, a polyimide resin, a polyamide resin, or the like.

Similarly to the display device 50a of the first embodiment, the display device 50g described above is configured to display an image by causing the light-emitting layer of the organic EL layer 23c to emit light as required, via the first TFTs 9a and the second TFTs 9b in each of the red subpixel Pr, the green subpixel Pg, and the blue subpixel Pb.

The display device 50g of the present embodiment can be manufactured by forming the organic EL element layer 30g by forming the pixel electrode 21a, the edge cover 22a, the organic EL layer 23c (the hole injection layer 1, the hole transport layer 2, the light-emitting layer, the electron transport layer 4, and the electron injection layer 5), and the common electrode 24 on the flattening film 19a of the TFT layer 20 by using a known method in a light-emitting element layer forming step of the manufacturing method for the display device 50a of the first embodiment, and then forming the sealing film 35 (the first inorganic sealing film 31, the organic sealing film 32, and the second inorganic sealing film 33) by using a known method. Further, although the TFT layer 20 is formed on the surface of the glass substrate layer 10a in the manufacturing method for the display device 50a according to the first embodiment, in a manufacturing method for the display device 50g of the present embodiment, for example, the TFT layer 20 may be formed on a surface of the resin substrate layer 10b formed on the glass substrate, the sealing film 35 may be formed, then laser light is radiated from the glass substrate side of the resin substrate layer 10b, and thereby the glass substrate can be peeled off from the lower surface of the resin substrate layer 10b.

According to the organic EL display device 50g of the present embodiment as described above, in the non-light-emitting region N of each of the red subpixels Pr, the green subpixels Pg, and the blue subpixels Pb, the pixel electrode 21a is provided with a reflective surface R having an uneven shape due to a plurality of recessed portions C formed on the surface of the flattening film 19a. For this reason, external light L is reflected in a direction different from the direction in which light is incident on the reflective surface R in the non-light-emitting regions N, and thus the reflected light visually recognized by the user is reduced. Accordingly, since the degradation of display quality caused by the reflection of the external light L is reduced in the organic EL display device 50g, the degradation of the display quality caused by reflection of the external light L can be reduced without using a circular polarizer.

In addition, according to the organic EL display device 50g of the present embodiment, since the plurality of recessed portions formed on the surface of the flattening film 19a are provided along the longer sides of each of the red subpixel Pr, the green subpixel Pg, and the blue subpixel Pb, external light L from the direction along the shorter sides of each of the red subpixel Pr, the green subpixel Pg, and the blue subpixel Pb can be effectively reflected on the reflective surface R in the non-light-emitting region N.

### Other Embodiments

Although the light-emitting function layer having a five-layer structure including the hole injection layer, the hole transport layer, the quantum dot light-emitting layer (light-emitting layer), the electron transport layer, and the electron injection layer is exemplified in each of the embodiments described above, the light-emitting function layer may have a four-layer structure including, for example, a hole injection layer, a hole transport layer, a quantum dot light-emitting layer (light-emitting layer), and an electron transport layer, a layered structure including a quantum dot light-emitting layer (light-emitting layer) and at least one layer among a hole injection layer, a hole transport layer, an electron transport layer, and an electron injection layer, or the like.

In addition, although the display device in which the electrodes of the TFTs connected to the pixel electrodes serve as drain electrodes is exemplified in each of the embodiments described above, the disclosure is also applicable to a display device in which the electrodes of the TFTs connected to the pixel electrodes are referred to as source electrodes.

### INDUSTRIAL APPLICABILITY

As described above, the disclosure is useful for self-emission display devices.

1. A display device comprising:
a base substrate layer;
a thin film transistor layer provided on the base substrate layer; and
a light-emitting element layer provided on the thin film transistor layer, the light-emitting element layer including a plurality of pixel electrodes, a common edge cover, a plurality of light-emitting function layers, and a common electrode layered in order corresponding to a plurality of subpixels constituting a display region,
wherein the edge cover covers a peripheral edge portion of each of the pixel electrodes,
in each of the subpixels, a portion of the plurality of pixel electrodes exposed from the edge cover constitutes a light-emitting region, and a portion of the plurality of pixel electrodes overlapping the edge cover constitutes a non-light-emitting region,
a reflective surface having an uneven shape is provided in the non-light-emitting region,
the plurality of subpixels include a red subpixel configured to emit red light, a green subpixel configured to emit green light, and a blue subpixel configured to emit blue light, the plurality of subpixels being provided adjacent to each other in a stripe shape, and
the number of light-emitting regions in the red subpixel, the number of light-emitting regions in the green subpixel, and the number of light-emitting regions in the blue subpixel differ from each other.

2. The display device according to claim 1,
wherein, in the non-light-emitting region, a resin film is provided on the thin film transistor layer side of the plurality of pixel electrodes,
a plurality of recessed portions extending in parallel to each other are provided on a surface of the resin film on the plurality of pixel electrodes side, and
the plurality of pixel electrodes in the non-light-emitting region include the reflective surface.

3. The display device according to claim 2,
wherein each of the subpixels is provided in a rectangular shape, and
the plurality of recessed portions are provided along a longer side of each of the subpixels.

4. The display device according to claim 2,
wherein each of the subpixels is provided in a rectangular shape, and
the plurality of recessed portions are provided along a shorter side of each of the subpixels.

5. The display device according to claim 2,
wherein the resin film is a flattening film provided on the light-emitting element layer side of the thin film transistor layer.

6. The display device according to claim 1,
wherein a reflective film is provided on the common electrode in the non-light-emitting region,
a plurality of recessed portions extending in parallel to each other are provided on a surface of the edge cover on the plurality of light-emitting function layers side, and
the reflective film includes the reflective surface.

7. (canceled)

8. The display device according to claim 1,
wherein the number of light-emitting regions in the blue subpixel is larger than the number of light-emitting regions in the green subpixel, and
the number of light-emitting regions in the red subpixel is smaller than the number of light-emitting regions in the green subpixel.

9. The display device according to claim 1,
wherein the plurality of subpixels include a red subpixel configured to emit red light, a green subpixel configured to emit green light, and a blue subpixel configured to emit blue light,
the blue subpixel is provided being larger than the red subpixel and the green subpixel,
the number of light-emitting regions in the blue subpixel is larger than the number of light-emitting regions in the green subpixel, and
the number of light-emitting regions in the red subpixel is smaller than the number of light-emitting regions in the green subpixel.

10. The display device according to claim 1,
wherein each of the light-emitting function layers includes a quantum dot light-emitting layer.

11. The display device according to claim 10,
wherein a cover glass layer is provided on the common electrode via an air layer.

12. The display device according to claim 10,
wherein a cover glass layer is provided on the common electrode via a layered body in which a high refractive index material layer made of a material having a relatively high refractive index and formed in the light-emitting region and a low refractive index material layer made of a material having a relatively low refractive index and formed in the light-emitting region and the non-light-emitting region are layered in order.

13. The display device according to claim 1,
wherein each of the light-emitting function layers is an organic electroluminescence layer.

14. The display device according to claim 13, comprising
A sealing film configured to cover the light-emitting element layer, the sealing film including a first inorganic sealing film, an organic sealing film, and a second inorganic sealing film layered in order.

15. A display device comprising:
a base substrate layer;
a thin film transistor layer provided on the base substrate layer; and
a light-emitting element layer provided on the thin film transistor layer, the light-emitting element layer including a plurality of pixel electrodes, a common edge cover, a plurality of light-emitting function layers, and a common electrode layered in order corresponding to a plurality of subpixels constituting a display region,
wherein the edge cover covers a peripheral edge portion of each of the pixel electrodes,
in each of the subpixels, a portion of the plurality of pixel electrodes exposed from the edge cover constitutes a light-emitting region, and a portion of the plurality of pixel electrodes overlapping the edge cover constitutes a non-light-emitting region,
a reflective surface having an uneven shape is provided in the non-light-emitting region,
the plurality of subpixels include a red subpixel configured to emit red light, a green subpixel configured to emit green light, and a blue subpixel configured to emit blue light,
the blue subpixel is provided being larger than the red subpixel and the green subpixel,
the number of light-emitting regions in the blue subpixel is larger than the number of light-emitting regions in the green subpixel, and
the number of light-emitting regions in the red subpixel is smaller than the number of light-emitting regions in the green subpixel.

16. The display device according to claim 15,
wherein, in the non-light-emitting region, a resin film is provided on the thin film transistor layer side of the plurality of pixel electrodes,
a plurality of recessed portions extending in parallel to each other are provided on a surface of the resin film on the plurality of pixel electrodes side, and
the plurality of pixel electrodes in the non-light-emitting region include the reflective surface.

17. The display device according to claim 16,
wherein each of the subpixels is provided in a rectangular shape, and
the plurality of recessed portions are provided along a longer side of each of the subpixels.

18. The display device according to claim 16,
wherein each of the subpixels is provided in a rectangular shape, and
the plurality of recessed portions are provided along a shorter side of each of the subpixels.

19. The display device according to claim 16,
wherein the resin film is a flattening film provided on the light-emitting element layer side of the thin film transistor layer.

20. The display device according to claim 15,
wherein a reflective film is provided on the common electrode in the non-light-emitting region,
a plurality of recessed portions extending in parallel to each other are provided on a surface of the edge cover on the plurality of light-emitting function layers side, and
the reflective film includes the reflective surface.

21. The display device according to claim 15,
wherein each of the light-emitting function layers includes a quantum dot light-emitting layer.
